(19) United States
(12) Patent Application Publication
(10) Pub. No.: US 2008/0164878 A1
(43) Pub. Date: Jul. 10, 2008

(54) Minimum Energy Shim Coils For Magnetic Resonance

(75) Inventors: Michael A. Morich, Mentor, OH (US); Shmaryu M. Shvartsman, Highland Heights, OH (US); Gordon D. DeMeester, Wickliffe, OH (US)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N. V., Eindhoven (NL)

(21) Appl. No.: 11/908,293

(22) PCT Filed: Mar. 3, 2006
(86) PCT No.: PCT/IB06/50682

§ 371 Date: Sep. 11, 2007

Related U.S. Application Data
(60) Provisional application No. 60/662,703, filed on Mar. 17, 2005.

(51) Int. Cl. G01R 33/3875

(52) U.S. Cl. 324/320

(57) ABSTRACT

In a magnetic resonance imaging system (10), a main magnet (20) generates a substantially uniform main magnetic field (B₀) through an examination region (14). An imaging subject (16) generates inhomogeneities in the main magnetic field (B₀). One or more shim coils are positioned adjacent a gradient coil (26). The gradient coil (26) is driven in halves by first and second power sources (28, 30) which have slightly dissimilar power characteristics which induce an inductive coupling between the shim coil (60) and the gradient coil (26). The shim coil (60) is designed to produce a desired magnetic field, such that the inductive coupling of the shim coils (60) to the gradient coil (26) is substantially minimized while the inhomogeneities in the main magnetic field (B₀) caused by the imaging subject are corrected based on prespecified spatial characteristics.

The following relates to the magnetic resonance arts. It finds particular application in magnetic resonance imaging, and will be described with particular reference thereto. However, it also finds application in magnetic resonance spectroscopy and other techniques that benefit from a main B₀ magnetic field of precisely known magnitude.

In magnetic resonance imaging, a temporally constant main B₀ magnetic field is produced with optimized spatial uniformity over a field of view. The MRI system typically includes a passive shimset to correct for intrinsic irregularities of the magnetic field. In addition to intrinsic irregularities, at higher main B₀ magnetic fields, such as at about 3 Tesla or higher, magnetic properties of the imaged subject, such as the magnetic susceptibility, increasingly distort the main B₀ magnetic field. These distortions are generally imaging subject-dependent, and may also depend upon the positioning of the imaging subject and the region of interest of the subject that is being imaged.

Main B₀ magnetic field uniformity can be improved for each patient using active shimming, in which dedicated shim coils produce a supplementary or shim magnetic fields that compensate for non-uniformities of the magnetic field caused by the imaged subject. The main magnet is usually superconducting, while the shim coils are usually resistive coils.

Typically, the shim coils are integrated with the gradient coils. Each shim coil is designed to produce a particular spherical harmonic correction. The magnitude of its interaction with the main field is governed by the amount of applied current. The gradient coils are used to provide known spatial deviations, typically linear gradients, in the main B₀ magnetic field. Similar to shim coils, the gradient coils excite spherical harmonics in addition to the desired lower order x, y, and z gradients. In many systems, both gradient and shim coils require fast switching of current, e.g., between slices.

The gradient coils of a gradient axis can be driven in halves. In some systems, the two halves gradient coils represent a complete electrical circuit in which the two half gradient coils are connected in series. Such a circuit is often driven by a single power source with a relatively high power rating. In other systems, the two half gradient coils are driven separately by two matched power sources with lower power ratings. Such a configuration is more desirable since both the gradient coils and the power source can be rated at a reduced voltage while the gradient coil current stays the same as when the halves are connected in series with a single power source. The lower voltage requirement is advantageous for reliability and testing requirements as compared to high voltage systems.

However, such independent connection introduces problems. The gradient coils and the shim coils are not DC devices but are driven by pulses. If everything were perfect, the current profiles would be perfectly matched between the two halves. If the two power sources differ slightly, e.g. in the current amplitude and phase, the Z² shim coils generally inductively couple to the two half gradient coils. Other shim coils may have similar problems.

One solution is to design the shim coils outside of the gradient coil assembly and use the gradient coils with shielding which lowers the coupling effect. However, the MR bore space is expensive. It is advantageous to use the free space between primary and shield gradient coils to integrate the shim coils. Additionally, it is advantageous to bring the shim coils closer to the imaging region to increase the efficiency of the magnetic field uniformity correction.

The present invention contemplates an improved apparatus and method that overcomes the aforementioned limitations and others.

According to one aspect, a magnetic resonance imaging apparatus is disclosed. A main magnet generates a substantially uniform main magnetic field through an examination region. A subject is positioned for imaging in the examination region. The subject generates inhomogeneities in the main magnetic field. A gradient coil selectively produces magnetic field gradients in the main magnetic field, the gradient coil being disposed adjacent the examination region. One or more shim coils selectively produce shim magnetic fields within the subject, which shim coils are positioned adjacent the gradient coil to reduce inhomogeneities in the main magnetic field caused by the subject. The shim coils are distributively designed for minimum energy and specific magnetic field behavior.

According to another aspect, a method of imaging is disclosed. A substantially uniform main magnetic field through an examination region is generated. A subject is positioned for imaging in the examination region, which subject produces inhomogeneities in the main magnetic field. Magnetic field gradients are selectively produced in the main magnetic field with a gradient coil, which is disposed adjacent the examination region. Magnetic fields distorted by the subject are shimmed with shim coils, which are positioned adjacent the gradient coil, which shimming includes reducing inhomogeneities in the main magnetic field caused by the subject with a distributed shim coils designed for minimum energy and specific magnetic field behavior.

One advantage resides in minimizing the coupling effect between the shim coil and the gradient.

Another advantage resides in efficient shimming of the subject induced inhomogeneity of the magnetic field.

Another advantage resides in improved B₀ field homogeneity, particularly at higher fields.

Yet another advantage resides in faster shim switching between slices.

Numerous additional advantages and benefits will become apparent to those of ordinary skill in the art upon reading the following detailed description of the preferred embodiments.

The invention may take form in various components and arrangements of components, and in various process operations and arrangements of process operations. The drawings are only for the purpose of illustrating preferred embodiments and are not to be construed as limiting the invention.

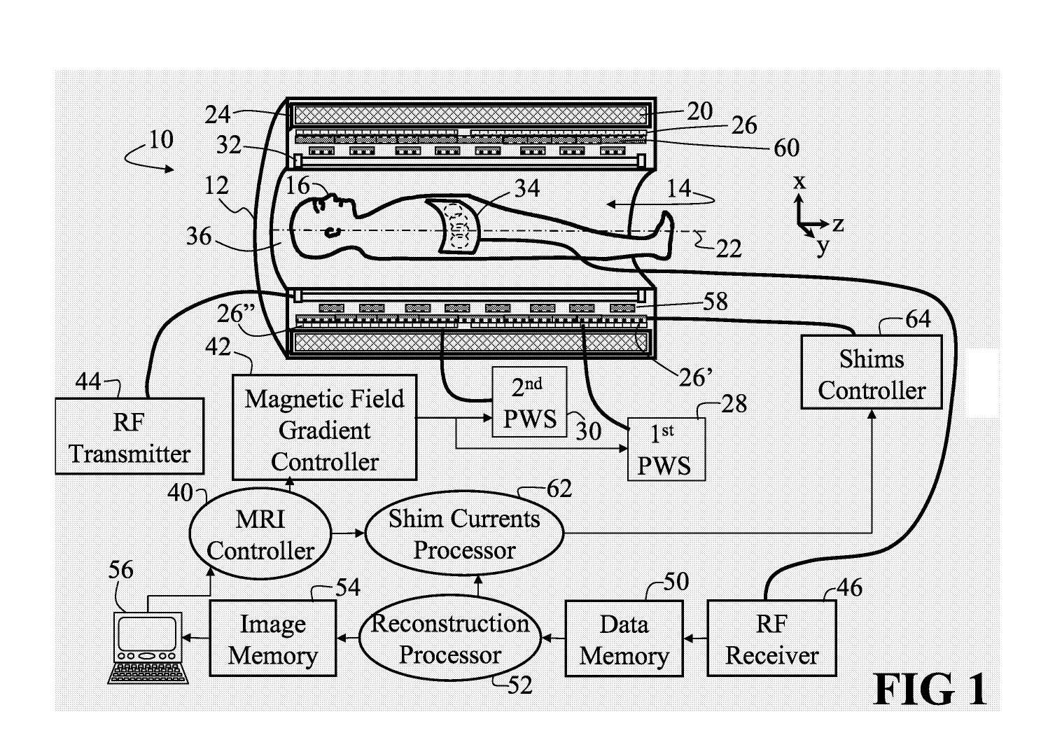

FIG. 1 diagrammatically shows a magnetic resonance imaging system implementing minimum energy target driven subject-specific magnetic field shimming;

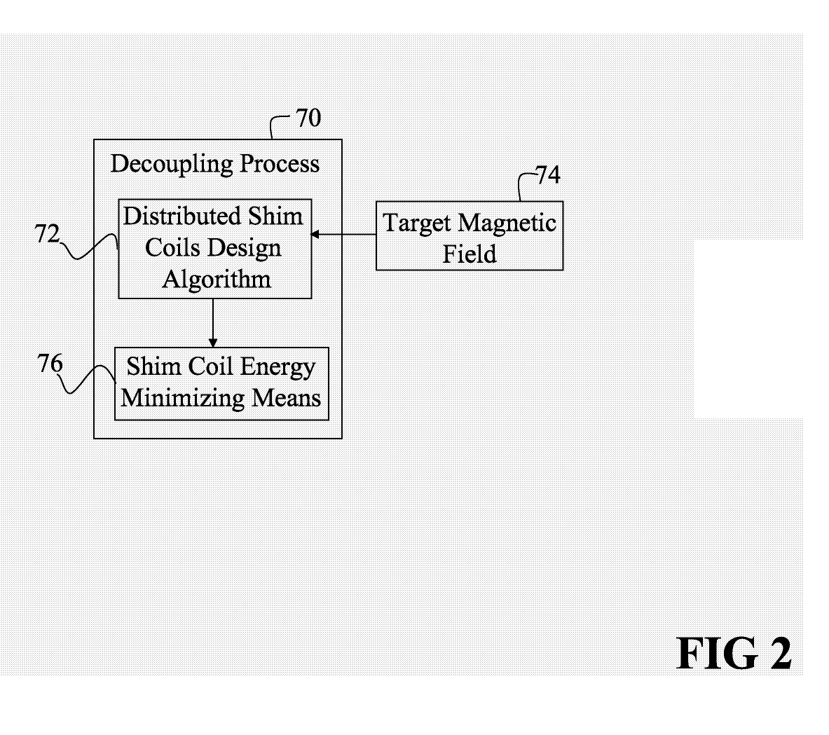

FIG. 2 diagrammatically shows a portion of shim coil design system;

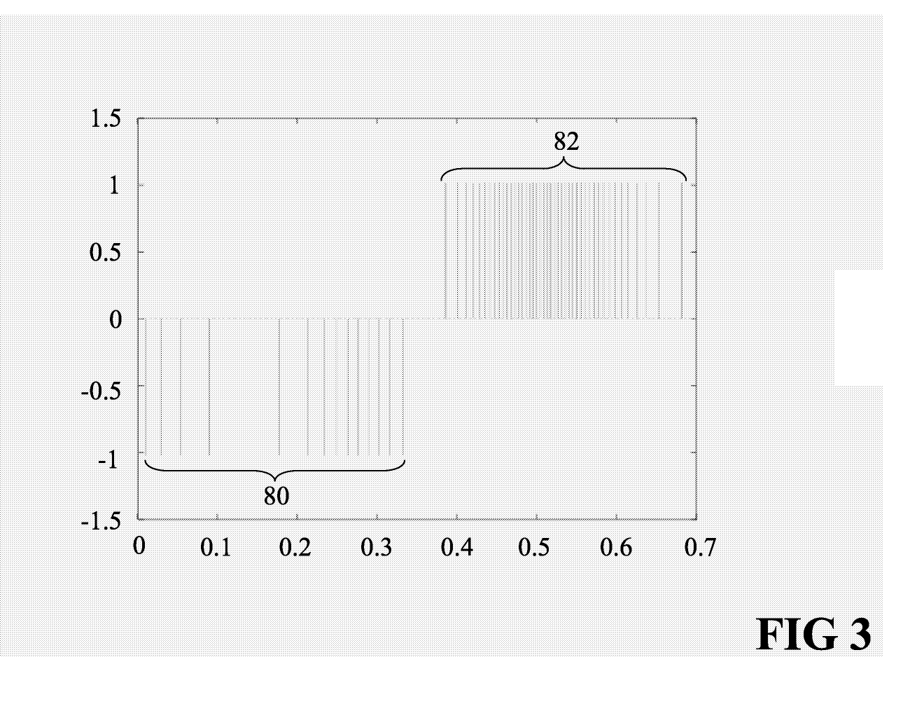

FIG. 3 shows a current layout of a distributed Z² shim coil without decoupling;

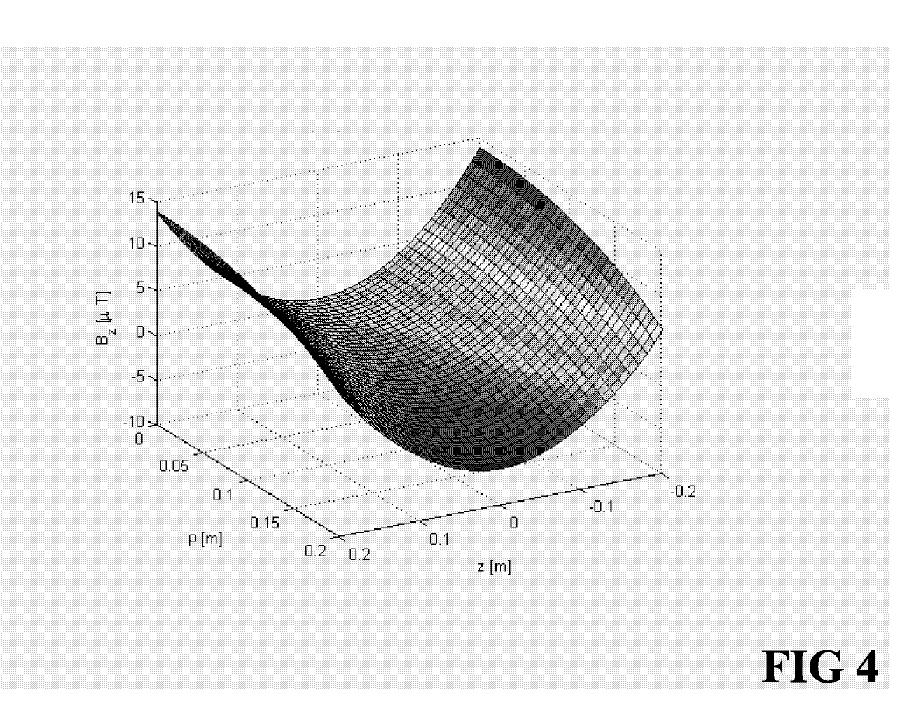

FIG. 4 shows a B_{z}-field from the distributed Z² shim coil without decoupling;

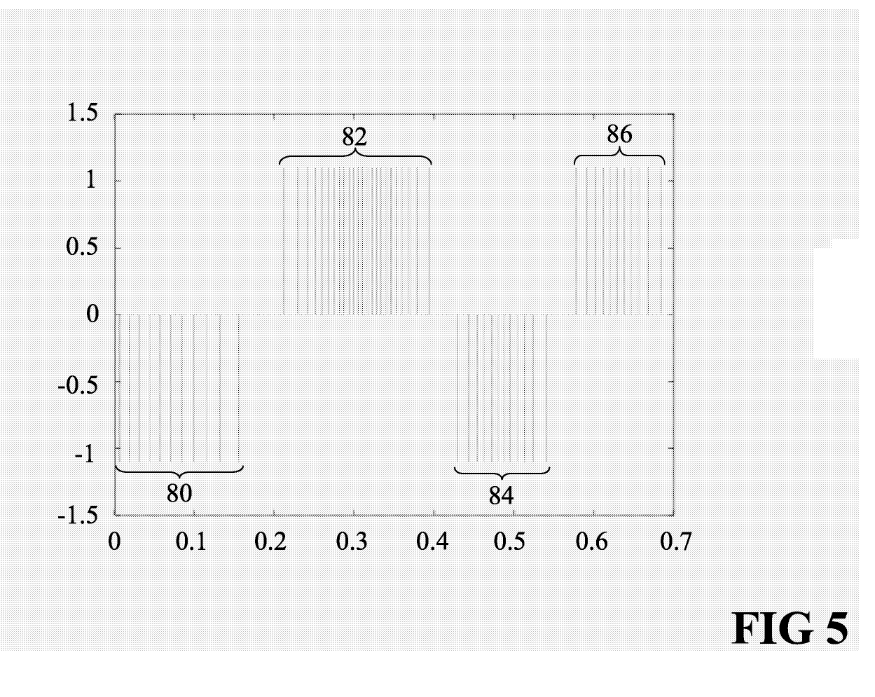

FIG. 5 shows a current layout of an improved Z² shim coil with decoupling;

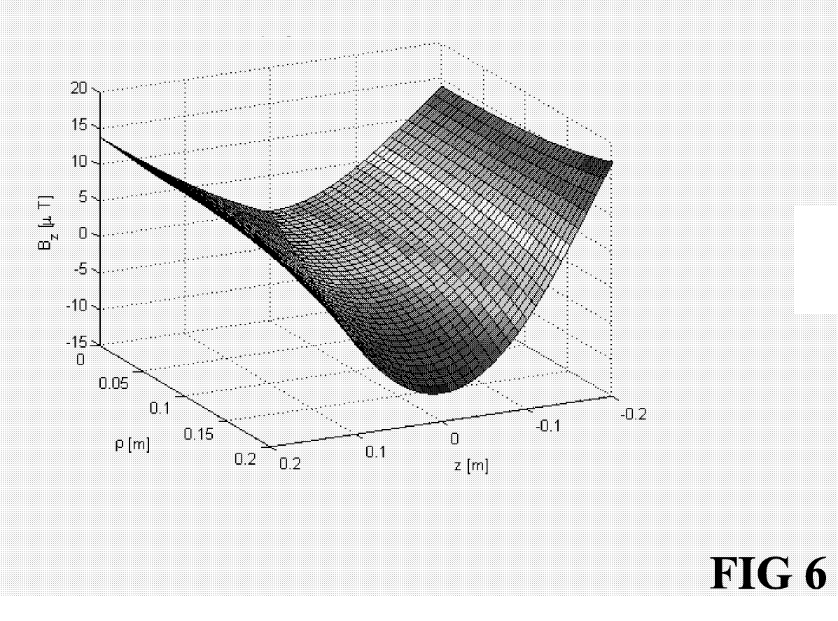

FIG. 6 shows a B_{z}-field from the improved Z² shim coil with decoupling;

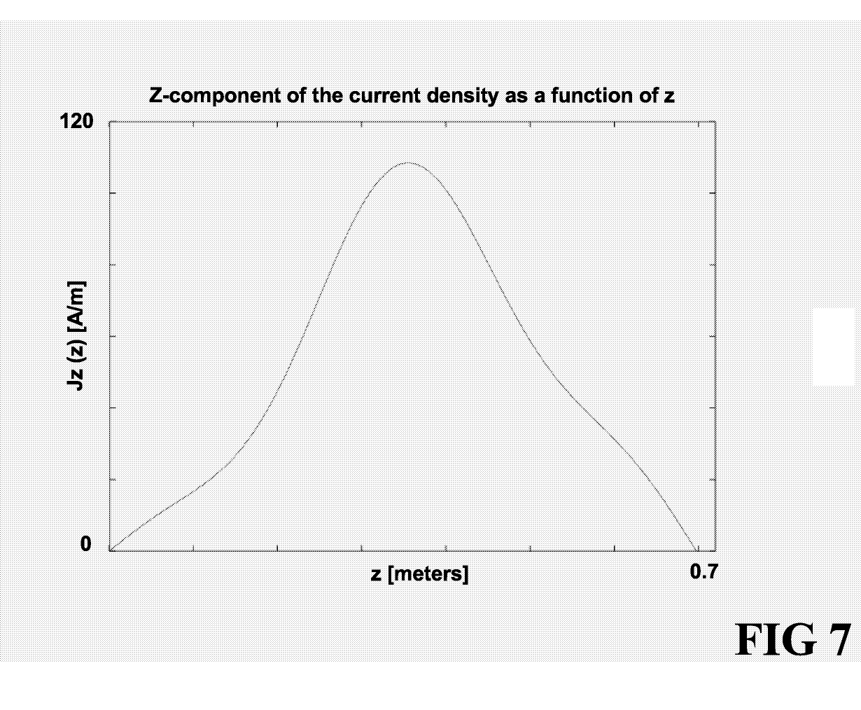

FIG. 7 shows a z-component of the continuous current density as a function of z of distributed (X²−Y²) shim coil without decoupling;

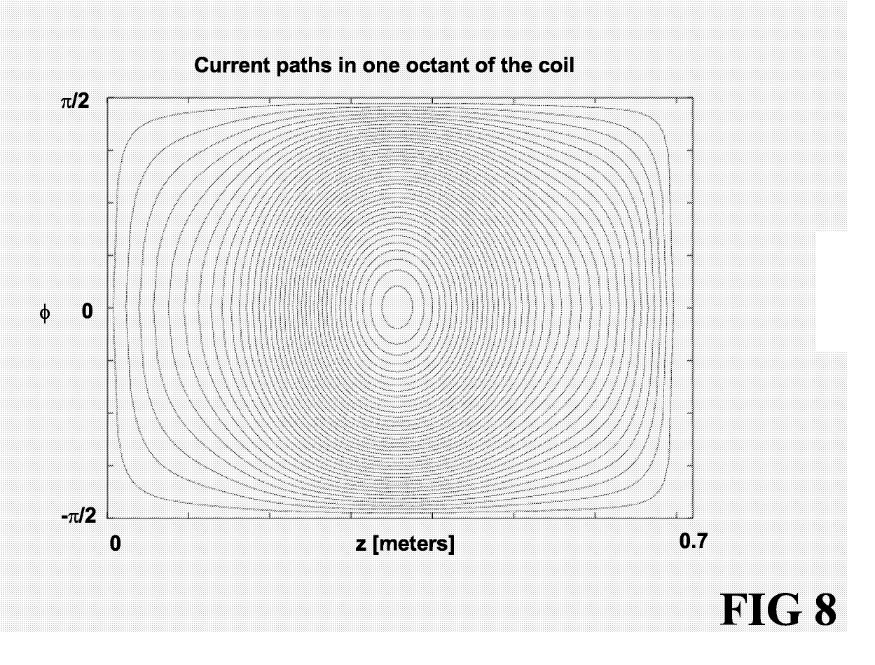

FIG. 8 shows the current paths on one of the eight octants of the coil of FIG. 7;

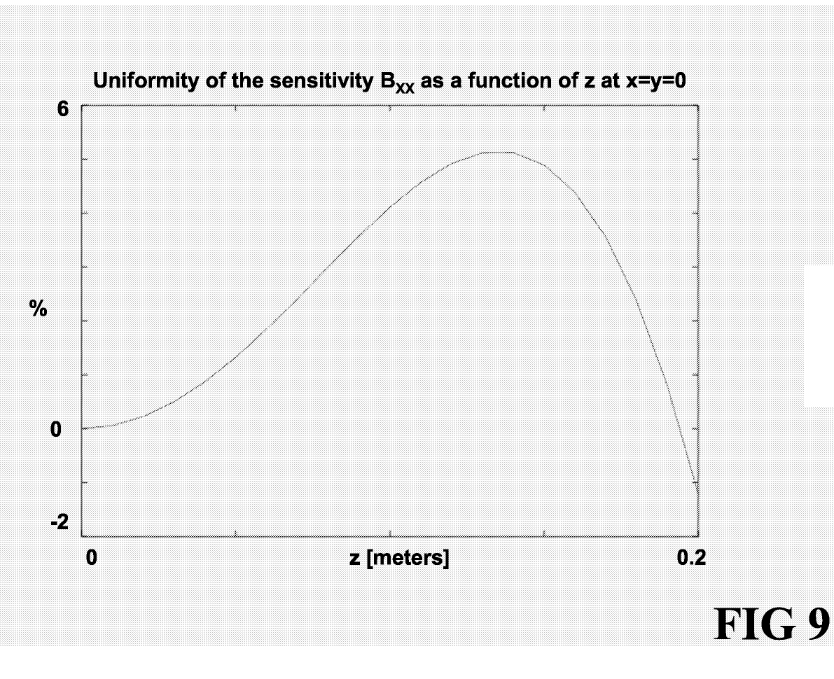

FIG. 9 shows the uniformity as a function of z at x═y═0 of the coil of FIG. 7;

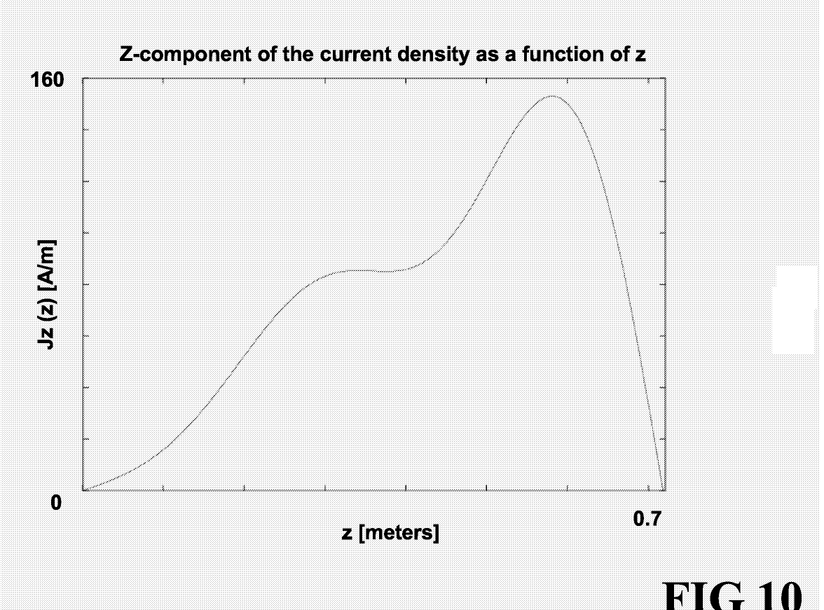

FIG. 10 shows the z-component of the continuous current density on the shim coil as a function of (X²−Y²) shim coil which is decoupled;

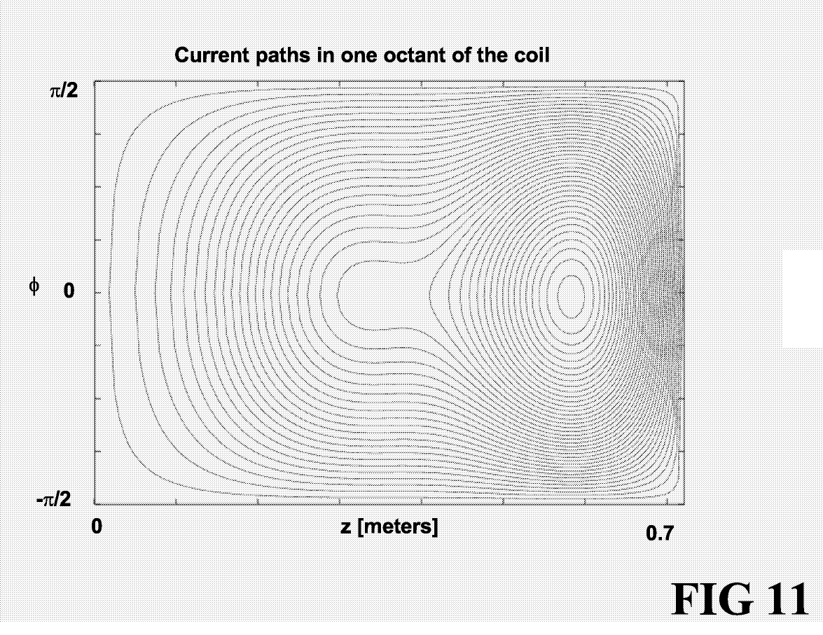

FIG. 11 shows the current paths on each of the eight octants of the coil of FIG. 10; and

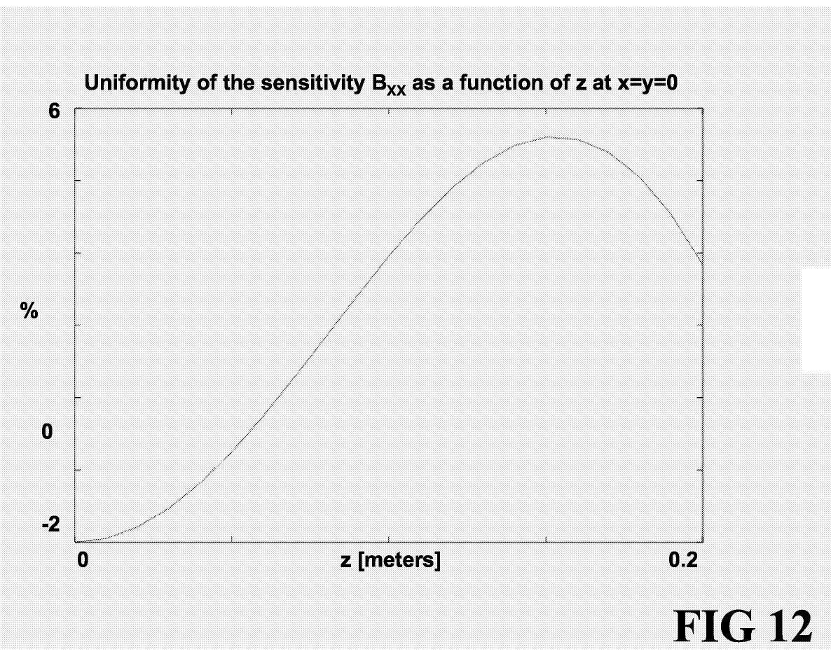

FIG. 12 shows the uniformity as a function of z at x═y═0 of the coil of FIG. 10.

With reference to FIG. 1, a magnetic resonance imaging scanner 10 includes a housing 12 defining a generally cylindrical scanner bore 14 inside of which an associated imaging subject 16 is disposed. Main magnetic field coils 20 are disposed inside the housing 12, and produce a main B₀ magnetic field parallel to a central axis 22 of the scanner bore 14. In FIG. 1, the direction of the main B₀ magnetic field is parallel to the z-axis of the reference x-y-z Cartesian coordinate system. Main magnetic field coils 20 are typically superconducting coils disposed inside cryoshrouding 24, although resistive main magnets can also be used.

The housing 12 also houses or supports magnetic field gradient coil(s) 26 for selectively producing known magnetic field gradients parallel to the central axis 22 of the bore 14, along in-plane directions transverse to the central axis 22, or along other selected directions. In one embodiment, the gradient coil(s) 26 are shielded with shielding coil(s) (not shown). The shielding coils are designed to cooperate with the gradient coil 26 to generate a magnetic field which has a substantially zero magnetic flux density outside an area defined by the outer radius of the shielding coil(s).

First and second power supplies 28, 30 provide power to associated halves of the gradient coils 26′, 26″. The housing 12 further houses or supports a radio frequency body coil 32 for selectively exciting and/or detecting magnetic resonances. An optional coil array 34 disposed inside the bore 14 includes a plurality of coils, specifically four coils in the illustrated example coil array 34, although other numbers of coils can be used. The coil array 34 can be used as a phased array of receivers for parallel imaging, as a sensitivity encoding (SENSE) coil for SENSE imaging, or the like. In one embodiment, the coil array 34 is an array of surface coils disposed close to the imaging subject 16. The housing 12 typically includes a cosmetic inner liner 36 defining the scanner bore 14.

The coil array 34 can be used for receiving magnetic resonances that are excited by the whole body coil 32, or the magnetic resonances can be both excited and received by a single coil, such as by the whole body coil 32. It will be appreciated that if one of the coils 32, 34 is used for both transmitting and receiving, then the other one of the coils 32, 34 is optionally omitted.

The main magnetic field coils 20 produce a main B₀ magnetic field. A magnetic resonance imaging (MRI) controller 40 operates magnetic field gradient controllers 42 to selectively energize the first and second power supplies 28, 30, and operates a radio frequency transmitter 44 coupled to the radio frequency coil 32 as shown, or coupled to the coil array 34, to selectively energize the radio frequency coil or coil array 32, 34. By selectively operating the magnetic field gradient coils 26 and the radio frequency coil 32 or coil array 34 magnetic resonance is generated and spatially encoded in at least a portion of a region of interest of the imaging subject 16. By applying selected magnetic field gradients via the gradient coils 26, a selected k-space trajectory is traversed, such as a Cartesian trajectory, a plurality of radial trajectories, or a spiral trajectory. Alternatively, imaging data can be acquired as projections along selected magnetic field gradient directions. During imaging data acquisition, a radio frequency receiver 46 coupled to the coils array 34, as shown, or coupled to the whole body coil 32, acquires magnetic resonance samples that are stored in a magnetic resonance data memory 50.

The imaging data are reconstructed by a reconstruction processor 52 into an image representation. In the case of Cartesian k-space sampled data or other data resampled appropriately, a Fourier transform-based reconstruction algorithm can be employed. Other reconstruction algorithms, such as a filtered backprojection-based reconstruction, can also be used depending upon the format of the acquired magnetic resonance imaging data. For SENSE imaging data, the reconstruction processor 52 reconstructs folded images from the imaging data acquired by each RF coil and combines the folded images along with coil sensitivity parameters to produce an unfolded reconstructed image.

The reconstructed image generated by the reconstruction processor 52 is stored in an image memory 54, and can be displayed on a user interface 56, stored in non-volatile memory, transmitted over a local intranet or the Internet, viewed, stored, manipulated, or so forth. The user interface 56 can also enable a radiologist, technician, or other operator of the magnetic resonance imaging scanner 10 to communicate with the magnetic resonance imaging controller 40 to select, modify, and execute magnetic resonance imaging sequences.

The main magnetic field coils 20 generate the main B₀ magnetic field, preferably at about 3 Tesla or higher, which is substantially uniform in the imaging volume of the bore 14. A set of passive shims 58 is disposed around the bore to compensate for the magnetic field non-uniformities and improve the uniformity of the B₀ field.

In addition to such inherent irregularities, when the associated imaging subject 16 is inserted into the bore 14, the magnetic properties of the imaging subject can distort the main B₀ magnetic field. To cancel the non-uniformity of the main B₀ magnetic field due to the distortions caused by the imaging subject, one or more active shim coils 60 housed or supported by the housing 12 provide active shimming of the main B₀ magnetic field. Preferably, the shim coils 60 are integrated with the gradient coil 26.

Ideally, each shim coil produces a magnetic field distribution within the bore 14 that includes B_{z} components, that is, magnetic fields directed parallel to the main B₀ magnetic field parallel to the z-direction. The B_{z} components are selected to enhance or partially cancel the main B₀ magnetic field produced by the main magnetic field coils 20 to correct for inherent non-uniformities, for distortion caused by the imaging subject 16, or the like. Specifically, a shim currents processor 62 determines appropriate shim currents for one or more of the shim coils 60 to reduce distortions in the main B₀ magnetic field with a superimposed gradient field. The shim currents processor 62 selects appropriate shim currents based on known configurations of the shim coils 60 and on the information of the magnetic field non-uniformity that needs to be corrected. Non-uniformity of the main B₀ magnetic field can be determined in various ways, such as by acquiring a magnetic field map using a magnetic field mapping magnetic resonance sequence executed by the scanner 10, by reading optional magnetic field sensors (not shown) disposed in the bore 14, by performing a priori computation of the expected magnetic field distortion produced by introduction of the imaging subject 16, or so forth. Magnetic field measurement sequences may be intermixed with the imaging sequence to check the main B₀ magnetic field magnitude periodically, e.g. after each slice or batch of slices. The shim currents processor 62 controls a shims controller 64 to energize one or more of the shim coils 60 at the selected shim currents. Because the half gradient coils 26′, 26″ are driven by separate power sources 28, 30, the current supplied to each half gradient coil 26′, 26″ slightly differs in phase and/or amplitude. This causes an inductive coupling between the shim coil(s) 60 and the half gradient coils 26′, 26″.

With reference to FIG. 2, a shim coil decoupling algorithm or processor or means 70 determines the winding pattern of the shim coil 60 in accordance with the Equations (1)-(13) below, which are solved by known computer programs and methods. As a result, the effect of coupling between the shim coil 60 and the gradient coil 26 is substantially minimized. The winding pattern of the shim coil 60 is determined to produce a desired target magnetic field while the shimming function is not reduced. More specifically, a distributed shim coil design algorithm or means or processor 72 designs distributed shim coils 60 using a minimum energy approach with a constraint of a magnetic field target 74, e.g. a field that behaves as Z², in accordance with the Equations (1)-(5) below. The stored magnetic energy of the shim coil(s) 60 is substantially minimized, e.g. the current is distributed over a surface. Traditionally, the shim coils 60 have been constructed from the discrete and bunched wires based on the Golay-saddle coils arrangements approach (U.S. Pat. No. 3,569,810). In the Golay arrangement, the wires are bunched together in saddle coils or loop arrangements at preferred locations. Such looped positioning approximates a centroid position that generates the desired shim coil harmonic. In the distributed coils arrangement, the distributed coils are positioned spaced over a surface such that a sum of centroid positions represent the desired harmonic. The distributed shim coils has showed to be more efficient in shimming the patient induced inhomogeneity of the magnetic field. A coil energy minimizing algorithm or processor or means 76 minimizes the energy of the shim coil 60 based on the desired field behavior such that the mutual inductance between the shim coil 60 and the gradient coil 26 is substantially minimized or eliminated in accordance with the equations (6)-(13) below, taking into account the existent half gradient coil circuit.

Designed in such manner, the distributed shim coils have minimum energy at the required spatial characteristics while the coupling between the shim coils and the half gradients is substantially minimized to approach 0.

When the subject cannot be shimmed completely due to local tissue susceptibility variations, it becomes desirable to shim dynamically per slice. Dynamic, i.e., pulsed, control of the shim coil current settings is also desirable. In one embodiment, the distributed shim coils are switched between slices or batches of slices. Dynamic control implies rise times may become important as well as transient effects, such as eddy currents and the like, and raises the potential use of shielded shim coil designs.

### EXAMPLE 1

### Axial Z² Shim Coil Design

Mathematically, in a cylindrical MRI system with a radius R, the shim coils are designed by calculating the current distribution on a cylinder of radius R, on which the shim coil of length 2*L is located. The current distribution is equal to

$$\vec{J} ( r ) = ( {e}_{ϕ} {f}_{0} ( z ) + {\sum }_{n = 1} {e}_{ϕ} {f}_{n} ( z ) cos ( n ϕ ) + {e}_{z} {q}_{n} ( z ) sin ( n ϕ ) ) δ ( ρ - R ) \qquad ( 1 )$$

where e_{φ}, e_{z} are azimuthal and axial unit vectors, respectively, and the functions fₙ(z), qₙ(z) obey the continuity equation

$$\frac{n}{R} {f}_{n} ( z ) = {q}_{n}^{′} ( z ) \qquad ( 2 )$$

where qₙ(z) is the derivative with respect to the axial variable z.

The first term in Equation (1) can be used to design a main magnet, Z-gradient coils, and the zonal shim coils. The z-component of the magnetic field produced by the term f₀(z) in the current densities of Equation (1) is

$${B}_{z}^{( 0 )} ( r ) = - \frac{μ R}{π} {\int }_{0}^{∞} k d {kT}_{0} ( k , ρ , R ) {\int }_{- L}^{L} {f}_{0} ( x ) cos ( k ( z - x ) ) d x \qquad ( 3 )$$

The second term in Equation (1) can be used to design X-gradient coils, and the Tesseral shim coils. The z-component of the magnetic field produced by the second term in the current densities of Equation (1) is

$${B}_{z}^{( n )} ( r ) = \frac{μ {R}^{2}}{π} \frac{cos ( n ϕ )}{n} {\int }_{0}^{∞} {k}^{2} d {kT}_{n} ( k , ρ , R ) {\int }_{- L}^{L} {q}_{n} ( x ) sin ( k ( z - x ) ) d x \qquad ( 4 )$$

In Equations (3) and (4), the function Tₙ(k, ρ, R) can be expressed in terms of Bessel functions of first kind and the derivatives of the Bessel functions:

Tₙ(k, ρ,R)=θ(ρ−R)I′ₙ(kR)Kₙ(kρ)+θ(R−ρ)Iₙ(kρ)K′ₙ(kR) (5)

Depending on the symmetry of the functions f₀(z), qₙ(z) and the order of the index “n”, different types of shim coils can be designed. For example, if f₀(z) is a symmetric function of z, second and even higher order zonal shim coils can be designed. If n=2 and qₙ(z) is a symmetric function of z, a second order Tesseral shim coil can be designed, such as a (X²−Y²) shim coil. The second order Tesseral shim coil X*Y can be obtained from (X²−Y²) shim coil by rotating it by the angle π/4. If n=2 and qₙ(Z) is an anti-symmetric function of z, a third order Tesseral shim coil Z*(X²−Y²) can be designed. The third order Tesseral shim coil Z*X*Y can be obtained from Z*(X²−Y²) shim coil rotating it by the angle π/4.

Preferably, the stored energy of the coil is minimized subject to desired field behavior inside the imaging volume and the mutual inductance between the shim coil and half of a transverse gradient is zero. The function to be minimized is

$${W}^{( n )} = {E}^{( n )} - {\sum }_{i = 1}^{N} ( {B}_{z}^{( n )} ( {r}_{i} ) - {B}_{i} ) {Λ}_{i} - Λ {M}_{Shim\_half \_TrG} , n = 0 , 1 , 2 , … \qquad ( 6 )$$

where E⁽ⁿ⁾ is the stored magnetic energy of the shim coil,
N is the number of constraint points ri inside the imaging volume where the z-component of the magnetic field has value Bᵢ, and
Λᵢ are the Lagrange multipliers.

The stored magnetic energy of the shim coil, when n is equal to 0, is equal to

$$\begin{matrix}{E}^{( 0 )} = \frac{μ}{2} {\int }_{0}^{∞} {W}_{( 0 )} ( k ) {F}_{( 0 )}^{2} ( k ) d k \\ where & ( 7 ) \\ {W}_{( 0 )} ( k ) = - {R}^{2} {I}_{0}^{′} ( kR ) {K}_{0}^{′} ( kR ) , and & ( 7.1 )\end{matrix}$$

F₍₀₎(k) is Fourier transform of the current density at n=0 which is equal to

$${F}_{( 0 )} ( k ) = {\int }_{- L}^{L} {f}_{0} ( z ) cos ( kz ) d z \qquad ( 8 )$$

The stored magnetic energy of the shim coil is equal to

$$\begin{matrix}{E}^{( n )} = \frac{μ}{2} {\int }_{0}^{∞} {W}_{( n )} ( k ) {F}_{( n )}^{( \pm ) 2} ( k ) d k \\ where & ( 9 ) \\ {W}_{( n )} ( k ) = - \frac{{R}^{4} {k}^{2}}{{n}^{2}} {I}_{n}^{′} ( kR ) {K}_{n}^{′} ( kR ) , and & ( 9.1 )\end{matrix}$$

F^{(±)}₍ₙ₎(k) is Fourier transform of the z-component of the current density which is equal to

$${F}_{( n )}^{( \pm )} ( k ) = {\int }_{- L}^{L} {q}_{( n )} ( z ) ( \begin{matrix}cos ( kz ) \\ sin ( kz )\end{matrix} ) d z \qquad ( 10 )$$

The sign +/− refers to the symmetry of the function qₙ(Z). More specifically, the sign “+” is used for a symmetric function, while the sign “−” is used for asymmetric function.

The mutual inductance M_{Shim}_{_{—}}_{half}_{_{—}}_{TrG} between the Z² shim and a half of an X-gradient coil can be expressed as

M_{Shim}_half_TrG=∫J^{(1/2X)}_{φ}(r)A^{(Z)}_{φ}(r)dr (11)

where A^{(Z)}_{φ}(r) is the vector potential produced by the Z²-shim, and J^{(1/2X)}_{φ}(r) is the φ component of the current density on the half of the X-gradient coil and can be expressed as

J^{(1/2X)}_{φ(}r)=(f^{(p)}_{φ}(z)δ(ρ−Rₚ)+f^{(s)}_{φ}(z)δ(ρ−R_{S}))cos(φ)θ((π/2)²−φ²) (12)

where (p) refers to the primary gradient coil, and (s) refers to the shield gradient coil.

The mutual inductance or co-energy between the shim coil and a half of a transverse coil is a linear functional in the current density on the shim coil. The mutual inductance term M_{Shim}_{_{—}}_{half}_{_{—}}_{TrG} of equation (11) is added to the equation (6) with a Lagrange multiplier to receive:

$$\begin{matrix}{W}^{( n )} = {E}^{( n )} - {\sum }_{i = 1}^{N} ( {B}_{z}^{( n )} ( {r}_{i} ) - {B}_{i} ) {Λ}_{i} - \\ Λ {M}_{Shim\_half \_TrG} = \\ = {E}^{( n )} - {\sum }_{i = 1}^{N} ( {B}_{z}^{( n )} ( {r}_{i} ) - {B}_{i} ) {Λ}_{i} - \\ Λ \int {J}_{ϕ}^{( 1 / 2 )} ( r ) {A}_{ϕ}^{( Z )} ( r ) d r\end{matrix} \qquad ( 13 )$$

With reference to FIGS. 3-4 and Table 1 below, there is shown an example of the design of a distributed second order fifty eight turn Z² shim coil represented by the loop positions. In this design, the mutual coupling term of the shim coil to the half gradient coil is not constrained. The radius R of the shim coil is selected to be equal to 0.3841 m. A half length of the shim coil L is selected to be equal to 0.7 m.

TABLE 1

| z | ρ | B_{z} [μT] |
|---|---|---|
| 0.0 | 0.0 | 0.0 |
| 0.14 | 0.0 | 3.1 |
| 0.2 | 0.0 | 6.4 |
| 0.17 | 0.2 | 1.0 |

With continuing reference to FIG. 3, a current layout on the distributed half Z²-shim coil, in which coupling is not constrained/balanced is shown. The current density is discretized and rescaled to I_{D}=1.01768A. There are distinct regions of negative and positive current, 80, 82 respectively, in this base shim coil design, in which the coupling between the shim coil and half gradient is not considered.

FIG. 4 shows a B_{z}-field from the distributed Z²-shim coil in which coupling is not balanced.

### Energy [J]=1.827E-3

### Current [I_{D}]=1.01768 A

### Inductance [μH]=3528.060

### Amut_hX_ZDP [μH]=−148.153

### Amut_hX_ZDS [μH]=126.791

### Amut_hX_ZDTot [μH]=−17.362

The B_{z}-field at p=0 and z=+/−0.2 is equal to 13.789 μT for the current I_{D} equal to 1.01768A.

With reference to FIGS. 5-6 and Table 2 below, there is shown an example of a design of a distributed second order fifty-eight turn shim coil represented by the loop positions. In this example, the mutual coupling to X gradient is constrained/balanced to be substantially close to zero, e.g. equal to a very small number. The radius R of the shim coil is selected to be equal to 0.3841 m. The half length of the shim coil L is selected to be equal to 0.7 m. The field constraints are manipulated using three numbers. First field constraint B₁ is imposed at ρ₁=0.00 m and z₁=0.00 m. Second field constraint B₂ is imposed at ρ₂=0.00 m and z₂=0.2 m. For example, B₂=B₁*factor₁* ρ²₂. Third field constraint B₃ is imposed at p₃=0.2 m and z₃=0.12 m. For example, B₃=B₂*factor₂. Here, factor, and factor₂ are the factors analogous to the factors used in the gradient coil design.

TABLE 2

| z | ρ | Bz [μT] |
|---|---|---|
| 0.0 | 0.0 | 0.0 |
| 0.2 | 0.0 | 8.4 |
| 0.12 | 0.2 | 0.6 |

FIG. 5 shows a current layout on the distributed half Z²-shim coil with a balanced coupling, the coupling of the shim coil to the half gradient coil is used as a constraint. The current density is discretized and rescaled to I_{D}=1.10071A. The negative and positive regions 80, 82 are pushed toward an isocenter. There are additional negative and positive current reversal regions 84, 86 at the ends of the coil. As illustrated, there is a substantial change in the current distribution of the Z² shim coil which is designed with a coupling constraint compared to the Z² shim coil which is designed with no consideration of the coupling between the shim coil and half gradient. The second negative/positive current regions 84, 86 counter the inductive coupling between the shim coil and half gradient.

FIG. 6 shows B_{z}-field from the distributed Z²-shim coil with a balanced coupling.

### Energy [J]=8.7952E-4

### Current [I_{D}]=1.10071A

### Inductance [μH]=1451.884

### Amut_hX_ZDP [μH]=−29.847

### Amut_hX_ZDS [μH]=29.940

### Amut_hX_ZDTot [μH]=9.3E−2

The B_{z}-field at ρ=0 and z=+/−0.2 is equal to 13.789 μT for the current I_{D} equal to 1.10071A. The energy is lower than that of the coil of the previous example.

### EXAMPLE 2

### Transverse (X²−Y²) Shim Coil Design

Similar to the axial shim coil design discussed above, the energy of the coil is minimized subject to (1) desired field behavior inside the imaging volume and (2) the condition that the mutual inductance between the shim coil and half of a transverse gradient is equal to zero. The current density in the X2−Y2 shim coil can be expressed as

\vec{J}(r)=e₁₀₀f₂(z)cos(2φ)+e_{z}q₂(z)sin(2φ))δ(ρ−R) (1′)

where e_{φ},e_{z} are azimuthal and axial unit vectors, respectively, and the functions fₙ(z),qₙ(z) obey the continuity equation

$$\frac{n}{R} {f}_{n} ( z ) = {q}_{n}^{′} ( z ) , n = 2 , \qquad ( {2}^{′} )$$

where q′ₙ(z) is the derivative with respect to the axial variable z.

The z-component of the magnetic field is given by the following expression:

$${B}_{z}^{( n )} ( r ) = - \frac{μ {R}^{2}}{π} \frac{cos ( 2 ϕ )}{2} {\int }_{0}^{∞} {k}^{2} d {kT}_{n} ( k , ρ , R ) cos ( kz ) {F}_{( n )} ( k ) \qquad ( {4}^{′} )$$

In the Equation (4′), the function Tₙ(k, ρ, R) can be expressed in terms of Bessel functions of first kind and the derivatives of the Bessel functions:

Tₙ(k, ρ, R)=θ(ρ−R)I′ₙ(kR)Kₙ(kρ)+θ(R−ρ)Iₙ(kρ)K′ₙ(kR) (5′)

The functional to be minimized is

$${W}^{( n )} = {E}^{( n )} - {\sum }_{i = 1}^{N} ( {B}_{z}^{( n )} ( {r}_{i} ) - {B}_{i} ) {Λ}_{i} - Λ {M}_{Shim\_half \_TrG} \qquad ( {6}^{′} )$$

where E⁽ⁿ⁾ is the stored magnetic energy of the shim coil,
N is the number of constraint points ri inside the imaging volume where the z-component of the magnetic field has value Bᵢ, and
Λᵢ are the Lagrange multipliers.

The stored magnetic energy of the shim coil can be expressed as

$$\begin{matrix}{E}^{( n )} = \frac{μ}{2} {\int }_{0}^{∞} {W}_{( n )} ( k ) {F}_{( n )}^{2} ( k ) d k \\ where & ( {9}^{′} ) \\ {W}_{( n )} ( k ) = - \frac{{R}^{4} {k}^{2}}{{n}^{2}} {I}_{n}^{′} ( kR ) {K}_{n}^{′} ( kR ) , and & ( {9.1}^{′} )\end{matrix}$$

F₍ₙ₎(k) is the Fourier transform of the current density that can be expressed as

$${F}_{( n )} ( k ) = {\int }_{- L}^{L} {q}_{( n )} ( z ) sin ( kz ) d z = \frac{2}{( kR )} {\int }_{- L}^{L} {f}_{( n )} ( z ) cos ( kz ) d z \qquad ( {10}^{′} )$$

As an important example, the mutual inductance between the (X²−Y²) shim and a half of an X gradient coil can be expressed as

M_{Shim}_{_{—}}_{half}_{_{—}}_{TrG}=∫J^{(1/2X)}(r)·A^{(Shim)}(r)dr (11′)

where j^{(1/2X)}(r) is the current density in the half gradient and can be expressed as

\vec{J}^{(1/2X)}(r)=\vec{J}₍ₚ₎^{(1/2X)}(r)

\vec{J}_{(p,s)}^{(1/2X)}(r)=(e_{φ}f₁^{(p,s)}(z)cos(φ)+e_{z}q₁^{(p,s)}(z)sin(φ))θ((π/2)²−φ²)δ(ρ−R_{(p,s)}) (12′)

In the Equations above, the letter (p) refers to the primary gradient coil, the letter (s) refers to the shield gradient coil, and A^{(Shim)}(r) is the vector potential produced by the (X²−Y²)-shim. The functions f^{(p,s)}₁(z) and q^{(p,s)}₁(z) satisfy the equation (2′) with n=1. The mutual inductance or co-energy between the shim coil and a half of a transverse coil is a linear functional in the current density on the shim coil. Therefore, this term is added to the functional (6′) with a Lagrange multiplier.

Similarly, the equations can be written for the decoupling of (X²−Y²) shim coil from a Y-gradient half. It should be noted that, by symmetry, the shim XY is decoupled from both X-gradient and Y-gradient halves.

The minimum energy approach with constraints distributes the current patterns of the coil in such a way that the coil has minimum energy/inductance and satisfies the input requirements.

With reference to FIGS. 7-9 and Table 3 below, there is shown an example of the design of a second order shim coil (X²−Y²) in which the mutual coupling with a half of an X gradient coil is not balanced. The radius R of the shim coil is chosen to be 0.3855 m. A half shim coil length L is selected to be equal to 0.7 m. The set of field constraints used in the following examples are listed in Table 3. The field constraints are manipulated using three numbers at φ=0. First field constraint B₁ is imposed at ρ₁=0.001 m and z₁=0.00 m. Second field constraint B₂ is imposed at ρ₂=0.001 m and z₂=0.2 m. For example, B₂=B₁*factor₁* ρ²₂. Third field constraint B₃ is imposed at ρ₃=0.2 m and z₃=0.00 m. For example, B₃=B₂*factor₂.

TABLE 3

| ρ(m) | φ | z [m] | B_{z} μ[T] |
|---|---|---|---|
| 0.001 | 0.0 | 0.0 | 1.E−4 |
| 0.001 | 0.0 | 0.2 | 0.98.E−0 |
| 0.200 | 0.0 | 0.0 | 4E−1 |

FIG. 7 shows z-component of the continuous current density as a function of z. The current density is discretized with thirty-eight turns each carrying current of I=1.01A. The current paths on one of the eight octants of the coil are shown in FIG. 8. The rest of the three octants for positive z of FIG. 7 are shifted in the azimuthal direction by the multiples of π/2. Four octants for z<0 are mirror image of those for positive z. The inductance of the coil is 3558.8 μH and the mutual coupling to the half X-gradient is 29.9 μH. The sensitivity of the shim coil is defined as

$${B}_{xx} ( r ) = \frac{1}{I} \frac{\partial {}_{}^{2}{B}{}_{z}^{} ( r )}{\partial x \partial x} , {B}_{xy} ( r ) = \frac{1}{I} \frac{\partial {}_{}^{2}{B}{}_{z}^{} ( r )}{\partial x \partial y} , \\ {B}_{yy} ( r ) = \frac{1}{I} \frac{\partial {}_{}^{2}{B}{}_{z}^{} ( r )}{\partial y \partial y} \qquad ( 14 )$$

At the point r=0 the sensitivities are equal to

Bₓₓ(0)=+727.2[πT|m|m|A], B_{xy}(0)=0, B_{yy}(0)=−727.2[πT|m|m|A]

FIG. 9 shows the uniformity (percent variation of the sensitivity) as a function of z at x=y=0.

With reference to FIGS. 10-12 and reference again to Table 3 above, there is shown an example of a second order shim coil (X²- y²), in which the mutual coupling with half an X gradient coil is constrained to be zero. The radius R of the shim coil is selected to be equal to 0.3855 m. The half-length L of the shim coil is selected to be equal to 0.71 m. The set of constraints used are listed in Table 3.

FIG. 10 shows the z-component of the continuous current density on the shim coil as a function of z. The current density is discretized with thirty-eight turns each carrying current of I=1.566A. The current paths on each of the eight octants of the coil are shown in FIG. 11. The rest of the three octants for positive z are shifted in the azimuthal direction by multiples of π/2. Four octants for z<0 are mirror image of those for positive z. The inductance of the coil is 4065.8 μH and the mutual coupling to the same half X-gradient is equal to −0.21 μH. The sensitivities at the point r=0 are defined as

Bₓₓ(0)=+510.93[πT|m|m|A], B_{xy}(0)=0, B_{yy}(0)=−510.93[πT|m|m|A]

FIG. 12 shows the uniformity (percent variation of the sensitivity) as a function of z at x=y=0. Table 4 below summarizes the comparison of the (X²−Y²) shim coil characteristics using the design without the mutual coupling constraints and design with mutual coupling constraint. As shown, the decoupled shim is less sensitive than the coupled shim, which is the tradeoff for obtaining decoupling. This problem can be addressed by increasing the current drive level. The decoupled shim would be detectable by local (surface) field measurement to detect the z-location of the peak J_{z} current. In the case of the decoupled shim this peak occurs much closer to the end of the shim coil. In the case of the coupled shim this peak is located close to the mid point between isocenter and the end of the shim coil.

TABLE 4

| | Shim coil is | Shim coil is not |
|---|---|---|
| | decoupled from | decoupled from |
| Property | gradient halves | gradient halves |
| Number of turns per octant | 38 | 38 |
| Inductance | 4065.8 | 3558.8 |
| Sensitivity [μT/m/m/A] at | | |
| r = 0 | | |
| B_{XX} | +510.93 | +727.2 |
| B_{YY} | −510.93 | −727.2 |
| B_{XY} | 0.0 | 0.0 |
| Mutual Inductance [μH] | −0.21 | 29.9 |
| to the X-Gradient half | | |

In one embodiment, instead of designing the shim coil to be decoupled from the gradient half by constraint, the coupling of the shim coil to the gradient half is minimized. For example, the following functional can be minimized.

$${W}^{( n )} = {E}^{( n )} + α {M}_{Shim\_half \_TrG}^{2} - {\sum }_{i = 1}^{N} ( {B}_{z}^{( n )} ( {r}_{i} ) - {B}_{i} ) {Λ}_{i} \qquad ( 15 )$$

where α is a parameter.

In another embodiment, instead of point field constraints, the derivative constraints to control the sensitivities and uniformity of the shims are used.

In one embodiment, to cancel the coupling of the shim coil to the half gradient, additional shim coils are added, preferably, at the ends of the gradient coil. The additional loops are added until the coupling between the shim coil and the half gradient coil becomes a sufficiently small number.

The embodiments and examples discussed and illustrated are applicable to both shielded and unshielded gradient coils.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

1. A magnetic resonance imaging apparatus comprising:
a main magnet for generating a substantially uniform main magnetic field through an examination regions;
a subject positioned for imaging in the examination region, which subject generates inhomogeneities in the main magnetic field;
a gradient coil for selectively producing magnetic field gradients in the main magnetic field, the gradient coil being disposed adjacent the examination region ; and
one or more shim coils for selectively producing shim magnetic fields within the subject, which shim coils are positioned adjacent the gradient coil to reduce inhomogeneities in the main magnetic field caused by the subject, which shim coils are distributively designed for minimum energy and specific magnetic field behavior.

2. The apparatus as set forth in claim 1, wherein the gradient coil is split into two halves and further including:
first and second power sources for supplying a pulsing electric power to each associated half gradient coil, the first and second power supplies having slightly dissimilar power characteristics which induce an inductive coupling between the shim coil and the gradient coil; and wherein the shim coil includes windings, which minimize the inductive coupling of the shim coil to the gradient coil.

3. The apparatus as set forth in claim 2, wherein the inductive coupling of the shim coil to the gradient coil is equal to or substantially not greater than 0.

4. The apparatus as set forth in claim 1, wherein the decoupling processor includes:
a distributed coils design processor for designing distributed shim coils with a current pattern which is distributed on a surface around a region defined by the gradient coil; and
a shim coil energy minimizing processor for designing the shim coils with a minimum stored energy associated with the current distribution.

5. The apparatus as set forth in claim 4, wherein the energy is a function which is minimized subject to (1) prespecified spatial characteristics to shim out the subject produced inhomogeneities and (2) minimized mutual inductance between the shim coil and the gradient coil.

6. The apparatus as set forth in claim 5, wherein the energy function is minimized according to equation:
$${W}^{( n )} = {E}^{( n )} - {\sum }_{i = 1}^{N} ( {B}_{z}^{( n )} ( {r}_{i} ) - {B}_{i} ) {Λ}_{i} - Λ {M}_{Shim\_half \_TrG} , n = 0 , 1 , 2 , …$$
where E⁽ⁿ⁾ is the stored magnetic energy of the shim coil,
rᵢ is constraint points inside the examination region,
Bᵢ is values of z-component of the magnetic field,
B⁽ⁿ⁾_{z} is gradient in the z-direction,
N is a number of constraint points r₁ inside the examination region where the z-component of the magnetic field has value Bᵢ,
Λᵢ are the Lagrange multipliers, and
M_{Shim}_{_{—}}_{half}_{_{—}}_{TrG} is the mutual inductance between the shim coil and one half of a gradient coil.

7. The apparatus as set forth in claim 2, wherein the coil windings store the energy, which is a minimized function subject to (1) prespecified spatial characteristics to shim out the subject produced inhomogeneities and (2) minimized mutual inductance between the shin coil and the gradient coil.

8. The apparatus as set forth in claim 7, wherein the energy function is minimized according to equation:
$${W}^{( n )} = {E}^{( n )} - {\sum }_{i = 1}^{N} ( {B}_{z}^{( n )} ( {r}_{i} ) - {B}_{i} ) {Λ}_{i} - Λ {M}_{Shim\_half \_TrG} , n = 0 , 1 , 2 , …$$
where E⁽ⁿ⁾ is the stored magnetic energy of the shim coil,
rᵢ is constraint points inside the examination region,
Bᵢ is values of z-component of the magnetic field,
B⁽ⁿ⁾_{z} is gradient in the z-direction,
N is a number of constraint points ri inside the examination region where the z-component of the magnetic field has value Bᵢ,
Λᵢ are the Lagrange multipliers, and
M_{Shim}_{_{—}}_{half}_{_{—}}_{TrG} is the mutual inductance between the shim coil and one half of a gradient coil.

9. The apparatus as set forth in claim 8, wherein the mutual inductance M_{Shim}_{_{—}}_{half}_{_{—}}_{TrG} between the shim coil and the half gradient coil can be expressed as
M_{Shim}_half_TrG=∫J^{(1/2X)}(r)·A^{(Shim)}(r)dr,
where A^{(Shim)}(r) is a vector potential produced by the shim coil; and
J^{1/2X}(r) is the current density on the half gradient coil.

10. The apparatus as set forth in claim 9, wherein the current density J^{(1/2X)}(r)on the half gradient coil is
J^{(1/2X)}_{φ}(r)=(f^{(p)}_{φ(}z)δ(ρ−Rₚ)+f^{(s)}_{φ}(z)δ(ρ−R_{S}))cos(φ)θ((π/2)²−φ²) (12)
where (p) refers to the primary gradient coil, and
(s) refers to the shield gradient coil.

11. The apparatus as set forth in claim 9, wherein the current density J^{(1/2X)}(r) in the half gradient coil is
\vec{J}^{(1/2X)}(r)=\vec{J}₍ₚ₎^{(1/2X)}(r)
\vec{J}_{(p,s)}^{(1/2X)}(r)=(e_{φ}f₁^{(p,s)}(z)cos(φ)+e_{z}q₁^{(p,s)}(z)sin(φ))θ((π/2)²−φ²)δ(ρ−R_{(p,s)})′
where (p) refers to the primary gradient coil, and
(s) refers to the shield gradient coil.

12. The apparatus as set forth in claim 2, wherein the windings generate reversal currents at shim coil ends, which reversal currents cancel the inductive coupling between the shim coil and the gradient coil.

13. A method of imaging, comprising:
generating a substantially uniform main magnetic field through an examination region;
positioning a subject for imaging in the examination region, which subject generates inhomogeneities in the main magnetic field;
selectively producing magnetic field gradients in the main magnetic field with a gradient coil, which is disposed adjacent the examination region; and
shimming magnetic fields distorted by the subject with shim coils, which are positioned adjacent the gradient coil, which shimming includes: reducing inhomogeneities in the main magnetic field caused by the subject with distributed shim coils designed for minimum energy and specific field behavior.

14. The method as set forth in claim 13, wherein the gradient coil is split into two halves and further including:
supplying electric power to associated halved of the gradient coil with first and second power supplies which have slightly dissimilar power characteristics which induce the inductive coupling between the shim coil and the gradient coil; and
decoupling the shim coils from the gradient coil such that the inductive coupling of the shin coils to the gradient coil is substantially minimized.

15. The method as set forth in claim 14, wherein the step of decoupling includes:
minimizing energy associated with the current distribution of the distributed shim coils.

16. The method as set forth in claim 15, wherein the step of decoupling further includes:
distributing shim coils near the gradient coil to position the shim coils close to the examination region.

17. The method as set forth in claim 15, wherein the energy of the shim coil is minimized subject to the desired characteristics of the shim coil field to shim out the subject produced inhomogeneities of the magnetic field and minimized mutual inductance between the shin coil and the gradient coil.

18. The method as set forth in claim 17, wherein the energy function is minimized according to equation:
$${W}^{( n )} = {E}^{( n )} - {\sum }_{i = 1}^{N} ( {B}_{z}^{( n )} ( {r}_{i} ) - {B}_{i} ) {Λ}_{i} - Λ {M}_{Shim\_half \_TrG} , n = 0 , 1 , 2 , …$$
where E⁽ⁿ⁾ is the stored magnetic energy of the shim coil,
rᵢ is constraint points inside the examination region,
Bᵢ is values of z-component of the magnetic field,
B⁽ⁿ⁾_{z} is gradient in the z-direction,
N is a number of constraint points ri inside the examination region where the z-component of the magnetic field has value Bᵢ,
Λᵢ are the Lagrange multipliers, and
M_{Shim}_{_{—}}_{half}_{_{—}}_{TrG} is the mutual inductance between the shim coil and one half of a gradient coil.

19. A method for designing a shim coil for correcting inhomogeneities of a magnetic field produced by an imaging subject in a magnetic resonance system, comprising:
selecting a radius for one or more shim coils;
selecting a half length for one or more shim coils;
selecting a number of constraints which are characteristic of a desired magnetic field of the shim coil;
minimizing shim coils stored energy with a distributed current pattern; and
designing distributed shim coils which are characterized by the distributed current pattern.

20. The method as set forth in claim 19, wherein the step of designing includes:
designing the distributed shim coils to substantially zero the coupling between the shim coils and the gradient coil.

21. The method as set forth in claim 20, wherein the stored energy is a function which is minimized according to equation:
$${W}^{( n )} = {E}^{( n )} - {\sum }_{i = 1}^{N} ( {B}_{z}^{( n )} ( {r}_{i} ) - {B}_{i} ) {Λ}_{i} - Λ {M}_{Shim\_half \_TrG} , n = 0 , 1 , 2 , …$$
where E⁽ⁿ⁾ is the stored magnetic energy of the shim coil,
rᵢ is constraint points inside the examination region,
Bᵢ is values of z-component of the magnetic field,
B⁽ⁿ⁾_{z} is gradient in the z-direction,
N is a number of constraint points ri inside the examination region where the z-component of the magnetic field has value Bᵢ,
Λᵢ are the Lagrange multipliers, and
M_{Shim}_{_{—}}_{half}_{_{—}}_{TrG} is the mutual inductance between the shim coil and one half of a gradient coil.

22. A shim coil designed by the method of claim 19.
